(19) United States
(12) Patent Application Publication
(10) Pub. No.: US 2016/0163634 A1
(43) Pub. Date: Jun. 9, 2016

(54) POWER REDUCED COMPUTING

(71) Applicant: Edward Seymour, Hillsboro, OR (US)

(72) Inventor: Edward Seymour, Hillsboro, OR (US)

(21) Appl. No.: 14/874,429

(22) Filed: Oct. 3, 2015

Related U.S. Application Data
(60) Provisional application No. 62/059,638, filed on Oct. 3, 2014.

(51) Int. Cl. H01L 23/528; H01L 23/522

(52) U.S. Cl. CPC H01L 23/528; H01L 23/5226

(57) ABSTRACT

Systems for performing computing operations in a power-reduced environment include a processor in communication with two data storage media and a non-grid-based power source, such as a solar, wind, or mechanical source. The first data storage is adapted for communication with a network, rapid receipt and transfer of data, and low power use, such as a flash drive. The second data storage is adapted for actuation to record and retrieve data, and to store data in a stationary state requiring no power, such as an optical disc drive. The first data storage medium can communicate data to and from a network, receive input, and provide output, while the second data storage medium can be used to archive stored data based on the actuation state thereof. To conserve power and improve integrity, signals can be transmitted as a complementary pair of signals, along two non-linear paths having overlapping and misaligned portions.

### BACKGROUND

1. Field of the Invention

The invention relates, generally, to power reduced computing.

2. Prior Art

Conventional computing devices are electrical in nature, whether reliant upon connection to a municipal electrical grid or another alternating current power source, or upon batteries, which typically must be recharged using a suitable grid-based power source. For a computing device to operate, a generally continuous supply of electricity is utilized, such that a processor, one or more data storage media, one or more input devices, and one or more displays and/or other types of output devices remain constantly accessible and operational. At any given time, only a portion of computer components are being utilized, and often at only a portion of the capacity thereof, such that the majority of power that is supplied to a computing device exceeds the quantity required to perform a particular function at a particular time.

### SUMMARY

Accordingly, an improved method and apparatus for power reduced computing is described below in the Detailed Description. For example, one disclosed embodiment provides a twisted pair of conducting lines through metal layers (commonly referred to as m1, m2, m3, etc.) on an integrated circuit, commonly referred to as an IC, chip, or a microchip. Conventional methods of bus transmission (e.g., on/across a chip) are considered inefficient due in part to leakage loss, especially on smaller devices, noise effects on single-ended transmissions, and challenges related to current return (e.g., using repeaters on a chip). In some embodiments, a twisted-pair of conducting lines, also called a conductor or a trace, along two non-intersecting (e.g., twisted) conductive paths along a chip, and/or within a coax conductor or similar conductor providing appropriate geometry, may transmit two signals (e.g., a positive signal and the negative, inverse thereof). The receipt and reconciliation of a positive and negative pair of signals, transmitted along a “twisted” route can improve quality of the transmission, reduce the number of repeaters on a chip, etc.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 depicts a diagram of an embodiment of a system usable within the scope of the present disclosure.

FIG. 2 depicts an exemplary diagram of a typical chip power grid usable to transmit signals.

FIG. 3A depicts a diagram of a portion of a twisted pair embodiment of conducting lines through metal layers of an integrated circuit.

FIG. 3B depicts a diagram of a portion of a twisted pair embodiment of conducting lines through metal layers of an integrated circuit.

FIG. 3C depicts a diagram of a twisted pair embodiment of conducting lines through metal layers of an integrated circuit.

### DETAILED DESCRIPTION

Before describing selected embodiments of the present invention in detail, it is to be understood that the present invention is not limited to the particular embodiments described herein. The disclosure and description herein is illustrative and explanatory of one or more presently preferred embodiments of the invention and variations thereof, and it will be appreciated by those skilled in the art that various changes in the design, organization, order of operation, means of operation, equipment structures and location, methodology, and use of mechanical equivalents may be made without departing from the spirit of the invention.

As well, it should be understood the drawings are intended illustrate and plainly disclose presently preferred embodiments of the invention to one of skill in the art, but are not intended to be manufacturing level drawings or renditions of final products and may include simplified conceptual views as desired for easier and quicker understanding or explanation of the invention. As well, the relative size and arrangement of the components may differ from that shown and still operate within the spirit of the invention as described throughout the present application.

Moreover, it will be understood that various directions such as “upper”, “lower”, “bottom”, “top”, “left”, “right”, and so forth are made only with respect to explanation in conjunction with the drawings, and that the components may be oriented differently, for instance, during transportation and manufacturing as well as operation. Because many varying and different embodiments may be made within the scope of the inventive concept(s) herein taught, and because many modifications may be made in the embodiments described herein, it is to be understood that the details herein are to be interpreted as illustrative and non-limiting.

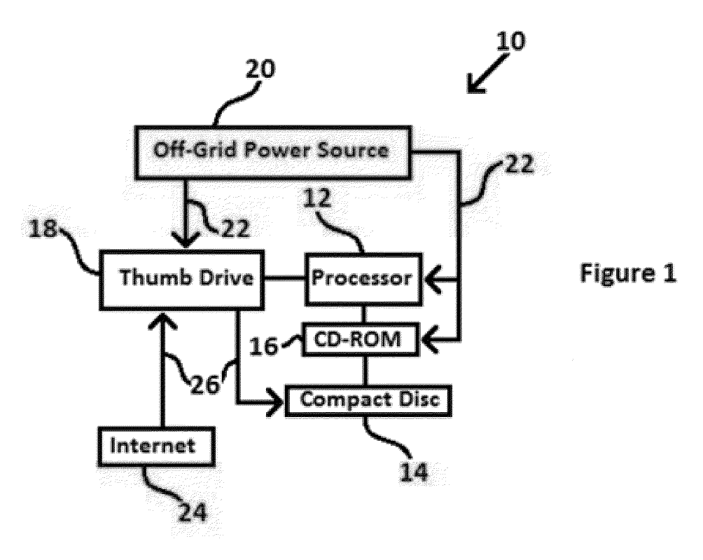

FIG. 1 depicts a diagram of an embodiment of a system (10) usable within the scope of the present disclosure. The depicted system (10) includes a computing device, represented by a processor (12), which is shown in communication with a low-power, non-transitory data storage medium, represented as a compact disc (14), accessible (e.g., for reading and/or writing) by a CD-ROM device (16). While FIG. 1 depicts a CD-ROM device (16) and associated storage media (e.g., the disc (14)), it should be understood that any manner of data storage able to be adapted for operation using means of power other than a conventional electrical grid can be used without departing from the scope of the present disclosure. A source of rapidly accessible (e.g., “flash”) memory is also shown in communication with the processor (12), represented as a thumb drive (18); however, it should be understood that any manner of data storage able to receive and/or transmit data and record such data and be adapted for operation using means of power other than a conventional electrical grid can be used without departing from the scope of the present disclosure. While not specifically depicted, it should be understood that a usable computing device could include any manner of local, non-transitory data storage media (e.g., a hard drive and/or removable and/or external storage), and any manner of input and/or output devices (keyboard, mouse, touchscreen, display, etc.).

The depicted system (10) is further shown including an “off-grid power source” (20), usable to provide power (22) (e.g., alternating and/or direct current) to one or more of the processor (12), the CD-ROM (16), and the thumb drive (18). As described previously, the off-grid power source (20) can include any manner of device able to provide power to one or more components the system (10) in the absence of access to a conventional electrical grid, such as a solar power source, a wind-based power source, a mechanical power source (e.g., a hand crank), or any combinations thereof. The off-grid power source (20) and/or any of the system components powered therefrom can include any manner of transformers, capacitors, conductors, insulators, and the like, as necessary to convert power from the power source (20) to voltages and/or amperage values suitable for use by respective system components.

The embodied system (10) can be used to access a network and/or other source of remote data, such as the Internet (24). In use, data (26) from the Internet (24) can be received and stored by the thumb drive (18), e.g., the membrane thereof, facilitated by the processor (12) if necessary. In an embodiment, remote processors, such as those accessible by the internet (24) could be used to facilitate the transfer of data (26) to the thumb drive (18), without requiring use of the system processor (12) and the provision of power thereto. The off-grid power source (20) can be used to provide power (22) to the thumb drive (18), and to the processor (12), if needed.

Data stored on the thumb drive (18) can be rapidly accessed by the processor (12), e.g., for performing computing functions related thereto (such as viewing, editing, and/or otherwise manipulating the data, as well as creating and/or deleting data). Data from the thumb drive (22) can also be archived on the compact disc (14), using the CD-ROM (16), and the processor (12), if necessary. Because the ability to transfer data between the thumb drive (18) and the compact disc (14) does not rely on any particular rate of rotation imparted to the disc (14) by the CD-ROM device (16), the off-grid power source (20) can provide any manner and/or quantity of power sufficient to actuate the CD-ROM device (16) at any non-zero rate of rotation.

As such, while FIG. 1 depicts data (26) transmitted from the thumb drive (18) to the compact disc (14), it should be understood that the transmission of data in the reverse direction is also possible. In summary, data (26) from the internet (24) can be initially received via the thumb drive (18) and archived on the compact disc (14) for storage and future retrieval, using a reduced amount of power. As needed, data from the compact disc (14) can be transferred to the thumb drive (22), also using very little power compared to conventional means, for access by the processor (12). Because the compact disc (14) is usable to archive the data (26) from the internet (24) substantially indefinitely, requiring no power to store the data (26) and only minimal power to transfer the data (26), it is not necessary for the system (10) to access the internet (24) again until a need for data beyond that which was received and stored on the thumb drive (18) and/or the compact disc (14) is determined. While FIG. 1 depicts data (26) transmitted from the internet (24) to the thumb drive (18), it should be understood that the transmission of data in the reverse direction is also possible. For example, the depicted system (10) could be used to edit and/or create data, which can be stored on the thumb drive (18) and/or the compact disc (14), for future transmission to the internet (24) or another network.

In summary, FIG. 1 depicts an embodiment of a system (10) usable in a power reduced and/or off-grid environment, e.g., by enabling archival of information using storage that does not require continuous power, a low-power means of writing and retrieving information from the storage media (that can be rate-independent and thus suitable for use with alternative means of power outside of an electrical grid), and a low-power means of accessing and communicating with the Internet or other networks. Additionally, the embodied system (10) can be useable for computing tasks in a “burst-based” manner. For example, the depicted system (10) need only access the Internet (24) (and remain accessible therefrom) during times when transmission of data (26) to and/or from the Internet (24) is necessary, such as when access to data not archived on the compact disc (14) or stored on the thumb drive (18) is desired. Further, one or more components the depicted system (10) need only be active (e.g., receive power) when specifically actuated to perform a defined task, after which the provision of power to such components can be ceased.

As such, the compact disc (14) or similar media can provide for long-term, reliable data storage when used in a manner that does not require conventional spinning/rotation of the disc. Data on discs is typically recorded in a spiral-shaped data track, and conventional access to such data requires modulation of the rotational speed (based on the distance between the center of the disc and the location of a desired item of data). As described above, conventional uses for CD/DVD-ROM devices primarily related to boot storage devices and sources of audio and/or video playback. Conventional CD/DVD-ROM devices are therefore optimized for speed at the expense of power efficiency.

In various embodiments, the system (10) of FIG. 1 and/or other similar systems could be powered using a solar power source and/or a hand crank as the sole power supply. The power requirements of a flash drive are generally low compared to other types of storage, enabling the thumb drive (18) or similar storage media to be used efficiently as an intermediate storage device, e.g., in conjunction with a resident operating system to perform the transfer operation. The depicted system (10) can thereby be used to backup and restore data, potentially using only solar and/or mechanical power sources.

In an embodiment, a portion of information available via the Internet or another network and/or source of data can be archived using an inexpensive source of data storage having to power requirements. For example, in an embodiment, one or more compact discs and/or digital video discs, in conjunction with a CD/DVD-ROM device can be used to record and store information from the Internet or another body of information. Conventional CD/DVD-ROM devices are designed to deliver data at a rate suitable for music and/or video playback and/or data transfer speed, having been designed at a time before data caches and RAM were inexpensive features, and require a variable speed motor due to the “spiral” shape along which data is recorded on a disc. As such, conventional CD/DVD-ROM devices are often designed to rotate continuously, even during times when data is not being transferred, resulting in inefficient power losses. However, when used primarily as a source of data storage, where no specific rate of rotation is necessary, archival and retrieval of information to or from a disc can be accomplished with a reduction in power, e.g., while a disc is simply retained in a stationary position until further archival and/or retrieval is desired. In an embodiment, such power can be provided using a solar source, a wind-powered source, a source of mechanical power (e.g., a hand crank) or other readily available alternatives to a conventional electrical grid.

In some embodiments, in conjunction with use of a CD/DVD-ROM device in such a manner, a generally low-power storage device, such as a thumb drive or a similar type of “flash” memory can be used to communicate and rapidly transmit information to and/or from the Internet or another type of network. For example, a thumb drive can be used for communication external to a computing device, e.g., via a satellite, and receipt and immediate storage of information, using a comparatively low amount of power when compared to conventional means. Subsequently, information from the thumb drive can be transferred to a disc for archival, and later retrieved from the disc, as needed. Once information has been stored in the thumb drive, the rate at which information is transmitted between the thumb drive (e.g., the membrane thereof) and a disc can be as slow or rapid as desired, using any available alternative source of power.

In addition to or in lieu of the devices and methods described above, embodiments usable within the scope of the present disclosure can include use of “burst-based” computing methods. As described previously, conventional computing methods require servers, networks, and computing devices to be continuously active and continuously available, which requires a large quantity of power, even at times where such power consumption is not necessary to meet contemporaneous computing needs. Conventional use of continuously available/accessible networks and/or computing devices also generates security risks. Embodiments usable within the scope of the present disclosure can include devices adapted to only transmit and/or receive information, as needed to perform specific functions, and in further embodiments, to only become powered on and/or active and/or accessible during such times of transmission and/or receipt. For example, a scripted transmission process can be used to acquire access to computing devices and/or components thereof or associated therewith.

As such, in the event of a catastrophic and/or unforeseen event, embodiments of the present systems and methods can allow for computing, even in the absence of a power grid. Further in the absence of the internet, a satellite connection can be used, e.g., by computing devices operating in a burst-based manner during times when solar, wind, or other alternative energy sources are available, to transmit and cache information received from other such computing devices on a thumb drive or other type of low power intermediate storage, until archived using low power storage, such as a compact disc. By using extended low power storage means such as this, an image of the internet can be formed, e.g., by connecting via a satellite connection to other off-grid computer centers, each responsible for a series of IP addresses.

In one example embodiment, a system for performing computing operations in a power-reduced environment can include a processor 12, a first non-transitory data storage medium in communication with the processor, wherein the first non-transitory data storage medium is adapted for communication with a network 14, and a second non-transitory data storage medium in communication with the processor 12 and the first non-transitory data storage medium, wherein the second non-transitory data storage medium is adapted for selective actuation to record data thereto and retrieve data therefrom. This example embodiment may further include a non-grid-based power source in communication with the processor, the first non-transitory data storage medium, the second non-transitory data storage medium, or combinations thereof, wherein the non-grid based power source is adapted to selectively actuate the second non-transitory data storage medium; and computer instructions on the first non-transitory data storage medium for instructing the processor to receive data from the network, store the data on the first non-transitory data storage medium, determine an actuation state of the second non-transitory data storage medium, and to transfer the data between the first non-transitory data storage medium and the second non-transitory data storage medium based on the actuation state, transmit data from the first non-transitory data storage medium to an output device in communication with the processor, and receive input data from an input device in communication with the processor and store the input data in the first non-transitory data storage medium.

By way of example, the first non-transitory data storage medium tray comprise a flash drive. Further, in this example embodiment the computer instructions may instruct the processor to transfer data between the membrane of the flash drive and the network, the second non-transitory data storage medium, or combinations thereof. In some embodiments, the second non-transitory data storage medium comprises an optical disc drive and at least one optical disc. Additionally, in these example embodiments, the non-grid-based power source may be adapted to selectively cause rotation of said at least one optical disc and actuation of the optical disc drive to access said at least one optical disc.

In some embodiments the non-grid-based power source may comprise a solar power source, a wind-based power source, a mechanical power source, or combinations thereof, as examples. An example mechanical power source may be a mechanical device adapted for manual manipulation by a user.

In these example embodiments, computer instructions may instruct the processor to determine a transmission state of the first non-transitory data storage medium, prevent communication between the first non-transitory data storage medium and the network if the transmission state indicates a state of non-transmission, and permit communication between the first non-transitory data storage medium and the network if the transmission state indicates a state of transmission.

In some embodiments, the processor may be adapted to transmit signals comprising an original signal transmitted on a conductor along a first non-linear path and an inverse signal complementary to the original signal transmitted along the conductor along a second non-linear path displaced in a horizontal or vertical direction relative to the first non-linear path, wherein at least a first portion of the first non-linear path and second non-linear path are parallel and aligned, and wherein at least a second portion of the first non-linear path and the second non-linear path are misaligned.

In some embodiments, a system may comprise a processor, an input device in communication with the processor, an output device in communication with the processor, a first non-transitory data storage medium in communication with the processor, wherein the first non-transitory data storage medium is adapted for communication with a network, wherein the first non-transitory data storage medium is further adapted for rapid receipt and transfer of data, and wherein the first non-transitory data storage medium is further adapted for low power usage, and a second non transitory data storage medium in communication with the processor and the first non-transitory data storage medium, wherein the second non-transitory data storage medium is adapted for selective actuation to record data thereto and retrieve data therefrom, and wherein the second non-transitory data storage medium is further adapted to store data in a stationary state requiring no power, and a non-grid-based power source in communication with the processor, the first non-transitory data storage medium, the second non-transitory data storage medium, or combinations thereof, wherein the non-grid based power source is adapted to selectively actuate the second non-transitory data storage medium computer instructions on the first non-transitory data storage medium for instructing the processor to receive data from the network, store the data on the first non-transitory data storage medium, determine an actuation state of the second non-transitory data storage medium, and transfer the data between the first non-transitory data storage medium and the second non-transitory data storage medium based on the actuation state, transmit data from the first non-transitory data storage medium to an output device in communication with the processor, and to receive input data from an input device in communication with the processor and store the input data in the first non-transitory data storage medium.

In some embodiments, a first non-transitory data storage medium may comprise a flash drive. In some embodiments, the computer instructions may instruct a processor to transfer data between the membrane of the flash drive and the network, the second non-transitory data storage medium, or combinations thereof. Additionally, in some embodiments the second non-transitory data storage medium may comprise an optical disc drive and at least one optical disc. In these example embodiments, the non-grid-based power source may be adapted to selectively cause rotation of said at least one optical disc and actuation of the optical disc drive to access said at least one optical disc. In these example embodiments, the non-grid-based power source may comprise a solar power source, a wind-based power source, a mechanical power source, or combinations thereof. By way of example, the non-grid-based power source may comprise a mechanical device adapted for manual manipulation by a user. In some embodiments, the computer instructions may instruct a processor to determine a transmission state of the first non-transitory data storage medium, prevent communication between the first non-transitory data storage medium and the network if the transmission state indicates a state of non-transmission, and permit communication between the first non-transitory data storage medium and the network if the transmission state indicates a state of transmission.

In some embodiments, a processor may be adapted to transmit signals including an original signal transmitted on a conductor along a first non-linear path, and an inverse signal complementary to the original signal transmitted along the conductor along a second non-linear path displaced in a horizontal or vertical direction relative to the first non-linear path, wherein at least a first portion of the first non-linear path and the second non-linear path are parallel and aligned, and wherein at least a second portion of the first non-linear path and the second non-linear path are misaligned.

In some embodiments, an example embodiment integrated circuit may comprise an original signal transmitted on a conductor along a first non-linear path, and an inverse signal complementary to the original signal transmitted along the conductor along a second non-linear path displaced in a horizontal or vertical direction relative to the first non-linear path, wherein at least a first portion of the first non-linear path and the second non-linear path are parallel and aligned, and wherein at least a second portion of the first non-linear path and the second non-linear path are misaligned.

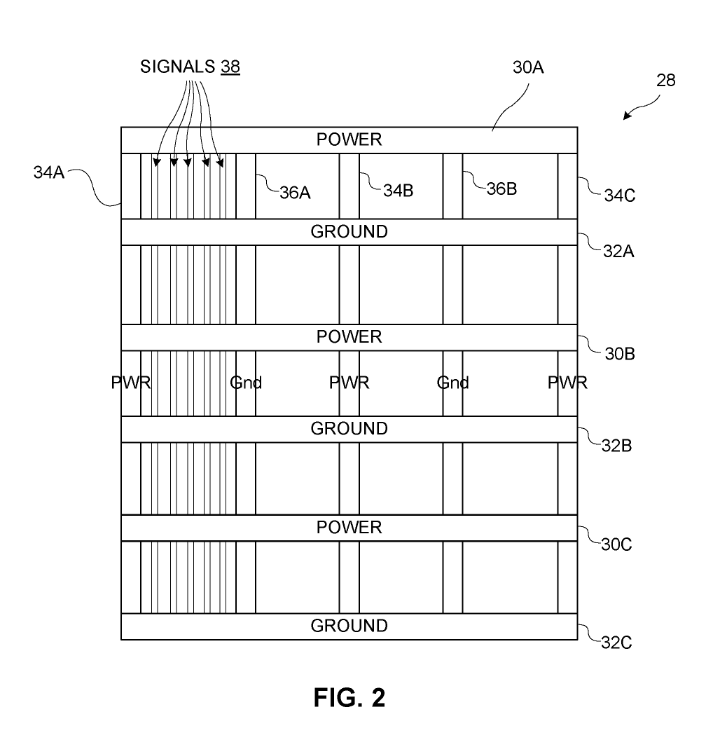

FIG. 2 depicts a diagram of an embodiment of a power grid (28) on a chip, usable to transmit digital signals (e.g., single-ended signals). The depicted power grid (28) is exemplary of a typical chip power grid usable to deliver power in various types of large macros and/or chips in metal layers (e.g., 2-5 layers). The power grid is shown including a plurality of spaced, parallel power elements (30A, 30B, 30C) having ground elements (32A, 32B, 32C) therebetween, these elements (30A, 30B, 30C, 32A, 32B, 32C) being positioned generally perpendicular to an additional set of generally parallel power elements (34A, 34B, 34C) having ground elements (36A, 36B) spaced therebetween. In use, signals (38) (e.g., single-ended digital signals) can be transmitted across the power grid (28). With the advent of smaller geometries, and the desire for devices having lower power consumption with equal or greater performance, the ability to transmit digital signals over large areas (especially single-ended digital signals) becomes increasingly more expensive and less accurate. Attempts to achieve these ends result in metal interconnections that are more resistive, while basic devices experience a greater leakage than previous alternatives.

In the depicted embodiment, the signals (38) are represented as vertical lines extending between power rails, each signal line representing a track available for signal routing. A typical chip can contain multiple power grids such as the power grid (28) depicted, and for communication of signals between chip cores, several such grids can be involved in the passage of single-ended signals therealong, with numerous buffers and/or inverters. Routing can be performed using a single-layer costing algorithm, with costs applied per unit of distance and, optionally, applied for vias. As such, conventional chips require frequent buffering of signals to reduce the effects of noise and maintain signal integrity.

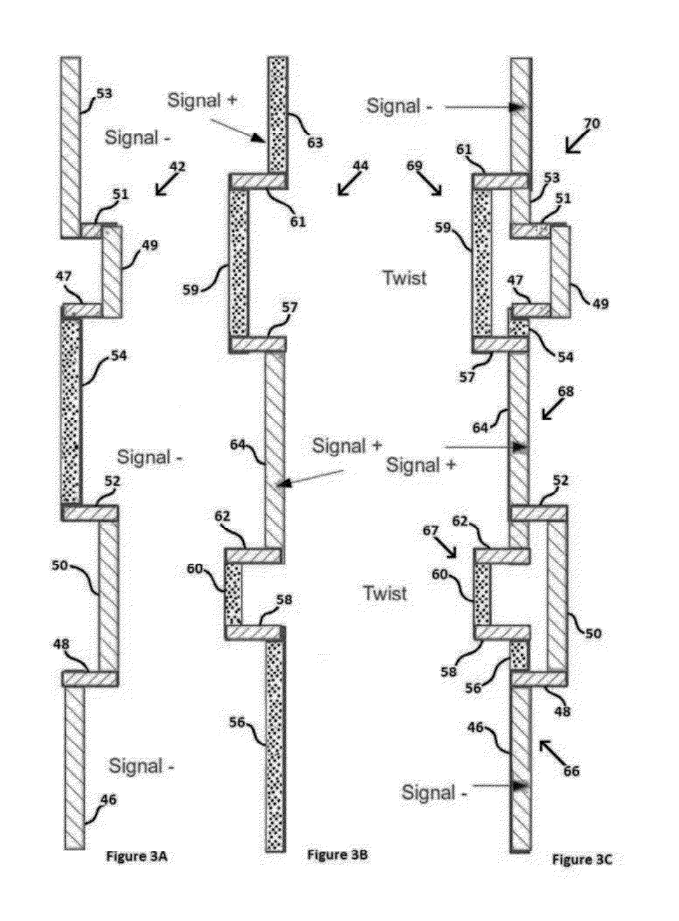

FIGS. 3A through 3C illustrate an exemplary embodiment of a “twisted pair” routing system and method, in which a signal (e.g., a “negative” signal) (42) can be transmitted simultaneously with its inverse (e.g., a corresponding “positive” signal) (44), in the same direction, e.g., along a chip or similar conductor, but within different layers of the chip. For illustrative purposes, FIGS. 3A through 3C depict embodied paths of the positive and negative signals (42, 44) through three adjacent metal layers within a chip. For example, regions of the diagrams including crosshatching extending from the upper left toward the bottom right can represent fourth layer metal within a chip, regions including cross-hatching extending from the upper right toward the bottom left can represent third layer metal within a chip, and layers including dots/stippling can represent second layer material within a chip. It should be understood that this exemplary selection of layers is only illustrative, and that any adjacent layers of routing could be employed in a similar manner without departing from the scope of the present disclosure. Additionally, while the depicted embodiment relates to vertically adjacent layers or routing, horizontal paths/routes could be used without departing from the scope of the present disclosure.

Specifically, FIG. 3A depicts a diagram of an embodiment of a path of a “negative” signal (42) (e.g., the inverse of the original and/or “true”) signal when transmitted through a chip or similar conductor. The negative signal (42) is shown including a first portion (46), transmitted along a first metal layer (e.g., fourth level metal). The negative signal (42) is then routed in a direction perpendicular to that of the first portion (46) (e.g., in either a horizontal or a vertical direction, depending on the characteristics of the chip through which the signal (42) is transmitted), as illustrated by a second portion (48) perpendicular to the first portion (46). In the depicted embodiment, the second portion (48) can indicate a path through third-level metal. The depicted signal (42) is then routed in a direction parallel to the first portion (46), as illustrated by the third portion (50), perpendicular to the second portion (48) and parallel to the first portion (46). As depicted, the third portion (50) can include a path through fourth-level metal. The signal (42) can then be routed in a direction perpendicular to the third portion (50), as illustrated by the fourth portion (52), then routed in a direction perpendicular to the fourth portion (52) (e.g., through third-level metal), then parallel to the first portion (46) but skew relative thereto (e.g., traveling in the same direction as the first portion (46), but in a different layer of the chip), as illustrated by the fifth portion (54), which can include a path through second-level metal. In the depicted embodiment, the fourth portion (52), is shown parallel to the second portion (48), extending in a direction opposite thereto such that the fifth portion (54) is generally aligned with the first portion (46); however, in other embodiments, the fifth portion (54) could potentially be skew relative to the first portion (52). The depicted path of the negative signal (42) further includes a second “twist,” illustrated by a sixth portion (47) perpendicular to the fifth portion (54), which can include a path through third level metal, a seventh portion (49) perpendicular to the sixth portion (47), which can include a path through fourth level metal, an eighth portion (51) perpendicular to the seventh portion (49), which can include a path through third level metal, and a ninth portion (53), perpendicular to the eight portion (51), which can include a path through fourth level metal. As described above, each of the alterations in the route of the signal (42) can be horizontal and/or vertical in nature, extending to any adjacent layer of material and/or any adjacent conductor.

FIG. 3B depicts a diagram of an embodiment of a path of a positive signal (44), e.g., the original/true signal, when transmitted through a chip or similar conductor. The depicted signal (44) includes a first portion (56), depicted including a path through second level metal. The positive signal (44) is then routed in a direction perpendicular to the first portion (56) (e.g., in either a horizontal or a vertical direction), as illustrated by the second portion (58), which can include a path through third-level metal. The depicted positive signal (44) is then routed in a direction perpendicular to the second portion (58) and parallel to the first portion (56), but skew relative thereto, as illustrated by the third portion (60), which can include a path through second level metal. The signal (44) can then be routed in a direction perpendicular to the third portion (60), as illustrated by the fourth portion (62), which can include a path through third level metal, then routed in a direction perpendicular to the fourth portion (64), as illustrated by the fifth portion (64), which can include a path through fourth level metal. In the depicted embodiment, the fourth portion (62) is shown parallel to the second portion (58), extending in a direction opposite thereto such that the fifth portion (64) is generally aligned with the first portion (56) (e.g., parallel to the first portion (56), but within a different layer of a chip); however, in other embodiments, the fifth portion (64) could be skew relative to the first portion (56). The depicted path of the positive signal (44) further includes a second “twist,” illustrated by a sixth portion (57) perpendicular to the fifth portion (64), which can include a path through third level metal, a seventh portion (59) perpendicular to the sixth portion (57), which can include a path through second level metal, an eighth portion (61) perpendicular to the seventh portion (59), which can include a path through second level metal, and a ninth portion (63), perpendicular to the eight portion (61), which can include a path through second level metal. As described above, each of the alterations in the route of the signal (44) can be horizontal and/or vertical in nature, extending to any adjacent layer of material and/or any adjacent conductor.

FIG. 3C depicts a diagram of an embodiment of a possible path of a “twisted pair” of signals (70) when transmitted through a chip and/or other type of conductor. The depicted twisted pair of signals (70) is formed by overlapping the path of the positive signal (44, shown in FIG. 3B) with that of the negative signal (42, shown in FIG. 3A). As such, the overlapping signals include regions of overlap, e.g., in which the positive and negative signals are transmitted parallel to one another, but in different layers of a chip, and twisted regions, in which the positive and negative signals are each routed to different layers within the chip (e.g., the route of the positive and negative signals could be interchanged, such that the positive signal is routed along the layer in which the negative signal was previously routed, and vice versa).

The first portion (66) of the twisted pair (70) is formed by overlapping the respective first portions (46, 56, shown in FIGS. 3A and 3B, respectively) of the positive and negative signals (42, 44, shown in FIGS. 3A and 3B, respectively), and extends along and/or parallel to a track within a chip/conductor along which the signals would travel. While parallel to one another, the first portions (46, 56) can be disposed in different layers of a chip and/or conductor (e.g., displaced in a horizontal or vertical direction relative to one another).

The respective second portions (48, 58) of the first and second signals are shown extending perpendicular to the first portion (66), in opposite directions; however, it various embodiments, it should he understood that the second portions (48, 58) could extend in the same directions relative to one another, but within different layers of a chip and/or conductor, or perpendicular to one another (e.g., in a vertical direction while the other portion extends in a horizontal direction), without departing from the scope of the present disclosure. The respective third portions (50, 60) of the signals are shown extending perpendicular to the respective second portions (48, 58), and parallel to the first portion (66). The respective fourth portions (52, 62) of the signals are shown extending perpendicular to the third portions (50, 60), in a direction opposite to that of the second portions (48, 58). The depicted second, third, and fourth portions of each signal collectively represent a first “twisted” region (67) of the signals. The depicted fifth portion (68) of the twisted pair of signals (70), formed by overlapping the path of the positive and negative signals (e.g., portions (54) and (64), shown in FIGS. 3A and 3B, respectively), is shown extending perpendicular to the fourth portions (52, 62) of the signals, and parallel to and generally in alignment with the first portion (66). As described previously, the overlapping fifth portions (54, 64) of the positive and negative signals (42, 44), can be parallel to one another, but positioned in different layers of a chip and/or conductor (e.g., displaced horizontal or vertically relative to one another). A second twisted region (69) is depicted, including the sixth portions (47, 57), seventh portions (49, 59), and eighth portions (51, 61) of the positive and negative signals, after which an overlapping region of which the ninth portion (53) of the negative signal is visible, is shown.

The depicted routing technique, illustrated in FIGS. 3A through 3C, can reduce leakage loss across a chip/bus/conductor, reduce the effects of noise, and provide an improved return, while enabling transmission of a signal to be completed using up to ten times fewer repeaters on a chip, or more. Use of a “twisted pair” routing technique can further allow the distance between buffers to be reduced, while requiring significantly less power to transmit signals having an integrity equal or greater than conventional alternatives. While the embodiments above are described with reference to transmission of a differential pair of signals, e.g., across a chip, other embodiments could include use of a coaxially isolated single-ended signal. As described previously, the choice of three adjacent layers of metal (e.g., second, third, and fourth level metal) within a chip is arbitrary, and any grouping of three adjacent layers of routing having any orientation and/or configuration could be used (including horizontal rather than vertical orientations) could be used without departing from the scope of the present disclosure. Each depicted section/portion of a signal can represent a half turn, while the entire depicted segment can represent a routing cell. Routing of a twisted pair of signals can be accomplished by abutment of adjacent routing cells that can be arranged in a row or column, enabling a “twisted pair” conductor of any desired length to be formed. In an embodiment, use of a differential driver and receiver, in the manner illustrated, can allow a greater noise tolerance, thereby allowing signals to traverse from 100 to 1000 times the distance common to a conventional single-ended transmission, without requiring use of repeater cells, significantly reducing the power requirements for transmitting the signal when compared to conventional alternatives, while providing a high signal integrity.

It will further be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or n some cases omitted. Likewise, the order of any of the above-described processes is not necessarily required to achieve the features and/or results of the embodiments described herein, but is provided for ease of illustration and description.

The subject matter of the present disclosure includes all novel and nonobvious combinations and subcombinations of the various processes, systems and configurations, and other features, functions, acts, and/or properties disclosed herein, as well as any and all equivalents thereof.

1. An integrated circuit comprising:
a first trace, having a first portion in a first metal layer, wherein the first portion is connected with a second portion in a second metal layer, wherein the second portion is perpendicular to the first portion and the second portion is connected to a third portion in the first metal layer, wherein the third portion is substantially parallel to the first portion and the third portion is connected with a fourth portion in the second metal layer and the fourth portion is perpendicular to the third portion, and the fourth portion is connected with a fifth portion in a third metal layer;
a second trace, having a first portion in the third metal layer, wherein the first portion is connected with a second portion in a second metal layer, wherein the second portion is perpendicular to the first portion and the second portion is connected to a third portion in the third metal layer, wherein the third portion is substantially parallel to the first portion and the third portion is connected with a fourth portion in the second metal layer and the fourth portion is perpendicular to the third portion, and the fourth portion is connected with a fifth portion in a first metal layer; and
the first portion of the first trace is substantially parallel to the first portion of the second trace.

2. The integrated circuit of claim 1, wherein the first portion of the first trace and the first portion of the second trace are collinear in the z-dimension of the integrated circuit.

3. The integrated circuit of claim 2, wherein the second portion of the first trace extends in an opposing direction from the direction the second portion of the second trace extends from the first portion of the second trace.

4. The integrated circuit of claim 1, wherein the fifth portion of the first trace is substantially parallel to the fifth portion of the second trace.

5. The integrated circuit of claim 1, wherein the first metal layer is the m2 layer of the integrated circuit.

6. The integrated circuit of claim 1, wherein he second metal layer is the m3 layer of the integrated circuit.

7. The integrated circuit of claim 1, wherein the third metal layer is the m4 layer of the integrated circuit.

8. The integrated circuit of claim 1, wherein the first race and the second trace twist around each other.

9. The integrated circuit of claim 1, wherein the first trace and the second trace form a twisted pair of conducting lines in the integrated circuit.

10. The integrated circuit of claim 1, wherein the third segment of the first trace is longer than the third segment of the second trace.
